(19) United States
(12) Patent Application Publication
(10) Pub. No.: US 2025/0286262 A1
(43) Pub. Date: Sep. 11, 2025

(54) DISPLAY DEVICE

(71) Applicants: Samsung Display Co., LTD., Yongin-si (KR); UNIST (ULSAN NATIONAL INSTITUTE OF SCIENCE AND TECHNOLOGY), Ulsan (KR)

(72) Inventors: Jae Uk CHOI, Yongin-si (KR); Gangil BYUN, Ulsan (KR); Kyuho LEE, Ulsan (KR); Ki Seo KIM, Yongin-si (KR); Young Sik KIM, Yongin-si (KR); In Nam LEE, Yongin-si (KR); Seungbin KIM, Ulsan (KR); Jin Myeong HEO, Ulsan (KR)

(21) Appl. No.: 18/944,179

(22) Filed: Nov. 12, 2024

(30) Foreign Application Priority Data
Mar. 5, 2024 (KR) 10-2024-0031157

(51) Int. Cl. H01Q 1/22; G01S 13/89; H01Q 1/48; H01Q 21/06

(52) U.S. Cl. CPC H01Q 1/22; G01S 13/89; H01Q 1/48; H01Q 21/06

(57) ABSTRACT

According to an embodiment, a display device may include a display panel including a display area and a non-display region disposed outside the display area, and including a flexible substrate including a protruded area extended from a portion of the non-display area, and an antenna circuit board connected to the protruded area. The non-display region includes a first non-display area positioned on a long side of the display panel, a second non-display area positioned on a short side of the display panel and a third non-display area positioned on a corner of the display panel, connecting the first non-display area with the second non-display area, and the display panel includes at least one transmitting antenna disposed at least partially in, or adjacent to, the first non-display area, adjacent first receiving antennas and a second receiving antenna disposed in the third non-display area.

### CROSS-REFERENCE TO RELATED APPLICATION

This application claims priority from Korean Patent Application No. 10-2024-0031157 filed on Mar. 5, 2024, in the Korean Intellectual Property Office and all the benefits accruing therefrom under 35 U.S.C. 119, the contents of which are incorporated by reference herein in its entirety.

### TECHNICAL FIELD

The present disclosure relates generally to a display device and more particularly to a display device including embedded antennas.

### DESCRIPTION OF THE RELATED ART

With recent advances in information technology, the demand for various types of display devices has expanded. Display devices are now prevalent in smart phones, tablets, laptops, digital cameras, vehicle navigators, and so forth.

A mobile electronic device may include an antenna for transmitting and receiving electromagnetic waves for wireless communication and/or various types of sensing. For example, the mobile electronic device may include a multi-input multi-output (MIMO) antenna for hand gesture recognition (HGR), which recognizes a user's hand gesture for receiving input commands. The MIMO antenna may include a plurality of transmitting antennas and a plurality of receiving antennas. The MIMO antennas may be disposed in a bezel of the mobile electronic device.

### SUMMARY

Embodiments of the present disclosure relate to a mobile display device having a reduced bezel size, in which antennas serving as sensors are disposed in a non-display area rather than a bezel.

According to an embodiment of the disclosure, a display device may include a display panel including a display area and a non-display region disposed outside the display area, and including a flexible substrate including a protruded area extended from a portion of the non-display area, and an antenna circuit board connected to the protruded area. The non-display region includes a first non-display area along a long side of the display panel, a second non-display area along a short side of the display panel and a third non-display area positioned on a corner of the display panel, connecting the first non-display area with the second non-display area, and the display panel includes at least one transmitting antenna disposed at least partly in or adjacent to the first non-display area, a plurality of first receiving antennas adjacent to the at least one transmitting antenna and disposed at least partly in or adjacent to the first non-display area, and a second receiving antenna disposed in the third non-display area.

In various embodiments:

The at least one transmitting antenna includes a first antenna, and the plurality of first receiving antennas include a second antenna and a third antenna, which are disposed in parallel with each other.

The first to third antennas are the same type of antenna and have the same shape.

The shape of the first to third antennas is different from a shape of the second receiving antenna.

The first to third antennas are dipole antennas, and the second receiving antenna is a monopole antenna.

The first to third antennas are asymmetric dipoles having an asymmetric shape when viewed on a plane of the display panel.

Each of the first to third antennas includes a first antenna electrode extended from a feed line, a second antenna electrode extended in one side direction from the first antenna electrode, having a first length, and a third antenna electrode extended from the second antenna electrode in the other side direction opposite to the one side direction, having a second length.

A first ground pattern connected to the second antenna electrode is disposed in the one side direction from the feeding line, the first ground pattern including a first ground etched area disposed in parallel with the feeding line, and a second ground pattern connected to the third antenna electrode is disposed in the other side direction from the feeding line, the second ground pattern including a second ground etched area disposed in parallel with the feeding line.

According to an embodiment of the disclosure, a display device may include a display panel including a display area and a non-display region disposed outside the display area, and including a flexible substrate including a protruded area extended from a portion of the non-display area, and an antenna circuit board connected to the protruded area. The non-display region includes a first non-display area positioned on a short side of the display panel, a second non-display area positioned on a long side of the display panel and a third non-display area positioned on a corner of the display panel, connecting the first non-display area with the second non-display area, and the display panel includes at least one transmitting antenna disposed in the first non-display area, a plurality of first receiving antennas adjacent to the at least one transmitting antenna in the first non-display area, and a second receiving antenna disposed in the third non-display area.

According to an embodiment of the disclosure, a display device may include a display panel including a display area and a non-display region disposed outside the display area, and including a flexible substrate including a protruded area extended from a portion of the non-display area, and an antenna circuit board connected to the protruded area. The non-display region includes a first non-display area positioned on a long side of the display panel, a second non-display area positioned on a short side of the display panel and a third non-display area positioned on a corner of the display panel, connecting the first non-display area with the second non-display area, and the display panel includes at least one transmitting antenna disposed in the first non-display area, a plurality of first receiving antennas adjacent to the at least one transmitting antenna in the first non-display area, and a second receiving antenna disposed in the second non-display area.

A polarization direction of each of the first to third antennas is the same as a polarization direction of the second receiving antenna.

According to an embodiment of the disclosure, a display device may include a display panel including a display area and a non-display region disposed outside the display area, the display panel including a flexible substrate including a protruded area extended from a portion of the non-display region, the display panel having a first side and a second side orthogonal to the first side; and an antenna circuit board connected to the protruded area. The non-display region includes a first non-display area along the first side of the display panel, a second non-display area along the second side of the display panel and a third non-display area on a corner of the display panel, connecting the first non-display area with the second non-display area, and the display panel includes at least one transmitting antenna disposed at least partly in or proximate to the first non-display area, a plurality of first receiving antennas disposed adjacent to the at least one transmitting antenna and at least partly in or proximate to the first non-display area, and a second receiving antenna disposed in the third non-display area.

In a display device according to the embodiments, antennas serving as sensors may be disposed in a non-display area, so that a bezel size of a mobile electronic device (within which the antennas may be otherwise disposed) may be reduced.

The effects according to the embodiments of the present disclosure are not limited to those mentioned above.

### BRIEF DESCRIPTION OF THE DRAWINGS

The above and other aspects and features of the present disclosure will become more apparent by describing in detail exemplary embodiments thereof with reference to the attached drawings, in which:

FIGS. 1 and 2 are plan views illustrating a display device according to an embodiment;

FIG. 3 a cross-sectional view or side view depicting an example structure of a portion of the display device of FIGS. 1 and 2 with a protruded area PA and a sub-area SBA in unfolded states;

FIG. 4 is a cross-sectional view or side view depicting an example structure of the display device of FIGS. 1 and 2 with the protruded area PA and the sub-area SBA in folded states;

FIGS. 5 and 6 are plan views illustrating a display device according to another embodiment;

FIG. 7 is a plan view illustrating any one corner of a display panel according to an embodiment;

FIG. 8 is a conceptual view illustrating an operation of antennas according to an embodiment;

FIGS. 9A and 9B are radar images obtained by sensing an object, which is moving in a first direction, by antennas according to an embodiment;

FIGS. 10A and 10B are radar images obtained by sensing an object, which is moving in a second direction, by antennas according to an embodiment;

FIGS. 11A and 11B are radar images obtained by sensing an object, which is moving in a third direction, by antennas according to an embodiment;

FIG. 12 is a result of an experiment for a polarization direction of antennas according to an embodiment;

FIG. 13 is a plan view illustrating a transmitting antenna and a first receiving antenna according to an embodiment;

FIG. 14 is a plan view illustrating any one corner of a display panel according to one embodiment;

FIG. 15 is a cross-sectional view taken along a portion of a display area of a display panel according to an embodiment; and

FIG. 16 is a cross-sectional view taken along a boundary between an antenna area of a display panel and a non-display area adjacent thereto according to an embodiment.

### DETAILED DESCRIPTION OF THE DISCLOSURE

Embodiments of the present inventive concept will now be described more fully hereinafter with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the claimed subject matter to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, specific embodiments will be described with reference to the accompanying drawings.

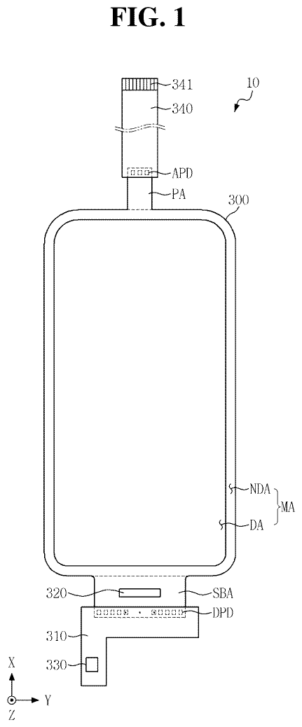

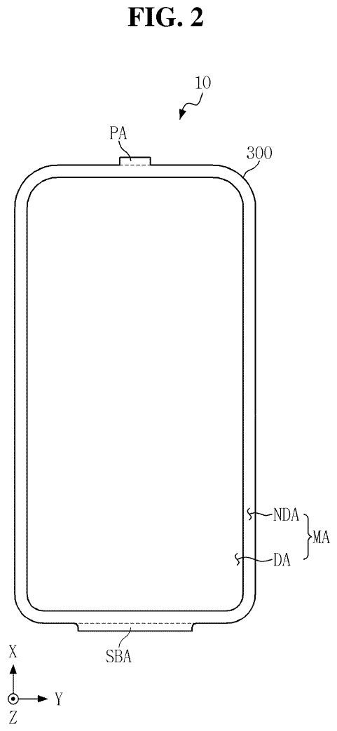

FIGS. 1 and 2 are plan views illustrating a display device according to an embodiment.

Referring to FIGS. 1 and 2, a display device 10 according to an embodiment may be applied to a mobile electronic device such as a mobile phone, a smart phone, a tablet personal computer (PC), a mobile communication terminal, an electronic diary, an electronic book, a portable multimedia player (PMP), a navigator and an ultra mobile PC (UMPC). In other examples, the display device 10 may be applied to a television, a laptop computer, a monitor, a signboard or a display unit of Internet of things (IoT), or a wearable device such as a smart watch, a watch phone, an eyeglasses-type display and a head mounted display (HMD). In still other examples, the display device may be applied to a center information display (CID) disposed in a dashboard, a center fascia or a gauge of a vehicle, a room mirror display, a side mirror of a vehicle, or a display disposed on a rear surface of a front seat as an entertainment for a rear seat of a vehicle.

In the example, a display panel 300 of the display device 10 may have a plate-like geometry with an oblong profile in the XY plane (the plane parallel to the display surface) as illustrated. The oblong profile may be substantially rectangular with rounded corners, such that the display device 10 has a pair of parallel long sides which are orthogonal to a pair of parallel short sides. In describing some embodiments of the present disclosure, a first direction (X-axis direction, hereafter, “X direction”) is a long side direction of the display device 10 and may be considered a vertical direction of the display device 10 when the display device is held vertically to present a “portrait” view. A second direction (Y-axis direction, hereafter, “Y direction”) is a short side direction of the display device 10 and may be considered a horizontal direction of the display device 10 when the display device 10 is held to present a portrait view. A third direction (Z-axis direction, hereafter, “Z direction”) may be a thickness direction of the display device 10. A corner where a long side in the X direction) and a short side in the Y direction meet (are connected) may be rounded to have a predetermined curvature, such that the connected long and short sides are orthogonal.

The display device 10 may include the display panel 300, a display circuit board 310, a display driving circuit 320, a touch driving circuit 330 and an antenna circuit board 340. A connector 341 may be formed on one side of the antenna circuit board 340.

The display panel 300 may be a light emitting display panel including a light emitting element. In other examples, the display panel 300 may be an organic light emitting display (OLED) panel using an organic light emitting diode including an organic light emitting layer; a micro light emitting diode display panel using a micro LED; a quantum dot light emitting display panel using a quantum dot light emitting diode including a quantum dot light emitting layer; or an inorganic light emitting display panel using an inorganic light emitting element including an inorganic semiconductor.

The display panel 300 may be a flexible display panel that is flexible and thus may be easily bent, folded or rolled. For example, the display panel 300 may be a foldable display panel that may be folded and unfolded; a curved display panel having a curved display surface; a bendable display panel in which an area other than a display surface is bent; a rollable display panel that may be rolled or unrolled; or a stretchable display panel that may be elongated.

The display panel 300 may include a main area MA, a sub-area SBA protruding from one side of the main area MA and a protruded area PA that protrudes from an opposite side of the main area MA.

The main area MA may include a display area DA for displaying an image and a non-display area (equivalently, “non-display region”) NDA which is a peripheral area of the main area MA. The display area DA may occupy most of the main area MA. The display area DA may be disposed at the center of the main area MA. The non-display area NDA may be a bezel that surrounds the display area DA. The non-display area NDA may be defined as an edge area of the display panel 300. The non-display area NDA may be referred to as “a dead space area”.

The sub-area SBA may protrude from one side (e.g., the lower side in FIG. 1) of the main area MA in the X. As shown in FIG. 1, a length of the sub-area SBA in the X direction may be shorter than that of the main area MA in the X direction, and the length of the sub-area SBA in the Y direction may be shorter than that of the main area MA in the Y direction, but embodiments of the present disclosure are not limited thereto.

Referring to FIG. 2, the sub-area SBA may be bent, and at least a portion of the bent sub-area SBA may be disposed below the display panel 300. In this case, at least a portion of the sub-area SBA may overlap the main area MA of the display panel 300 in the Z direction.

Display pads DPD may be disposed at one edge of the sub-area SBA. One edge of the sub-area SBA may be a lower edge of the sub-area SBA. The display circuit board 310 may be attached to the display pads DPD of the sub-area SBA. The display circuit board 310 may be attached to the display pads DPD of the sub-area SBA by using a conductive adhesive member such as an anisotropic conductive film and an anisotropic conductive paste. The display circuit board 310 may be a flexible printed circuit board (FPCB) that may be bent, a rigid printed circuit board (PCB) that is rigid and thus is not easily bent, or a composite printed circuit board that includes both a rigid printed circuit board and a flexible printed circuit board.

The display driving circuit 320 may be disposed on the sub-area SBA of the display panel 300. The display driving circuit 320 may receive control signals and power voltages, and may generate and output signals and voltages for driving the display panel 300. The display driving circuit 320 may be formed of an integrated circuit (IC).

The touch driving circuit 330 may be disposed on (e.g., attached to) the display circuit board 310. The touch driving circuit 330 may be formed of an integrated circuit.

The touch driving circuit 330 may be electrically connected to sensor electrodes of the sensor electrode layer of the display panel 300 through the display circuit board 310. The touch driving circuit 330 may output a touch driving signal to each of the sensor electrodes and sense a voltage change according to mutual capacitance of the sensor electrodes.

The sensor electrode layer of the display panel 300 may sense a “proximity touch” and/or a “contact touch”. Herein, “contact touch” means that an object, such as a person's finger or pen, comes into direct contact with a cover window disposed on the sensor electrode layer. Herein, “proximity touch” means that an object, such as a person's finger or pen, is positioned over the cover widow to be slightly spaced apart from the cover window, like hovering.

Display pixels of the display panel 300 and a power supply unit for supplying driving voltages for driving the display driving circuit 320 may be additionally disposed on the display circuit board 310. Alternatively, the power supply unit may be integrated with the display driving circuit 320, and in this case, the display driving circuit 320 and the power supply unit may be formed as one integrated circuit.

The protruded area PA may be an area that includes at least one element of a feeding line, a ground line or an antenna electrode of an antenna module for wireless communication. The protruded area PA may protrude from the opposite side of the main area MA in the X direction. For example, the opposite side of the main area MA may be an upper side of the main area MA. As shown in FIG. 1, a length of the protruded area PA in the X direction may be shorter than that of the main area MA in the X direction, and a length of the protruded area PA in the Y direction may be shorter than that of the main area MA in the Y direction, but the embodiment of the present disclosure is not limited thereto.

As shown in FIG. 2, at least a portion of the protruded area PA may be bent, and at least a portion of the bent protruded area PA may be disposed below the display panel 300. In this case, at least a portion of the protruded area PA may overlap the main area MA of the display panel 300 in the Z direction.

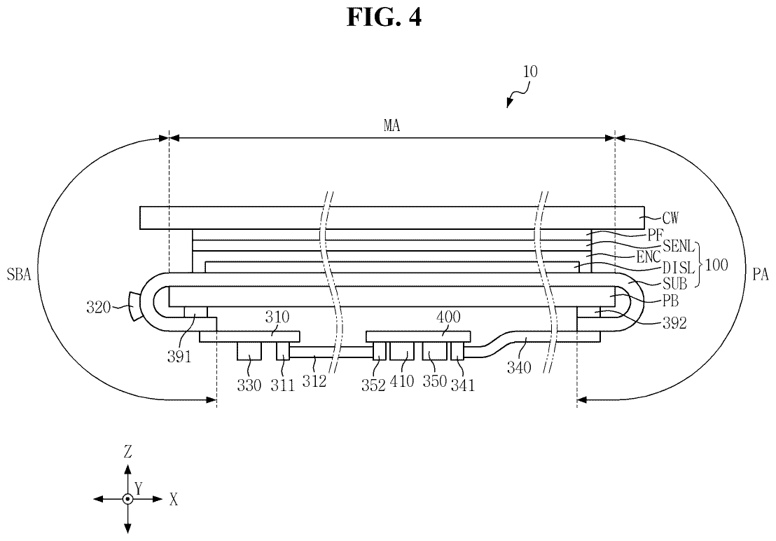

Antenna pads APD may be disposed at one edge of the protruded area PA. The antenna circuit board 340 may be attached onto the antenna pads APD of the protruded area PA. The antenna circuit board 340 may be attached onto the antenna pads APD of the protruded area PA by using a conductive adhesive member such as an anisotropic conductive film and an anisotropic conductive adhesive. One side of the antenna circuit board 340 may include a connector 341 connected to a main circuit board 400 on which an antenna driving circuit (350 of FIG. 4) is packaged. The antenna circuit board 340 may be a flexible printed circuit board (FPCB).

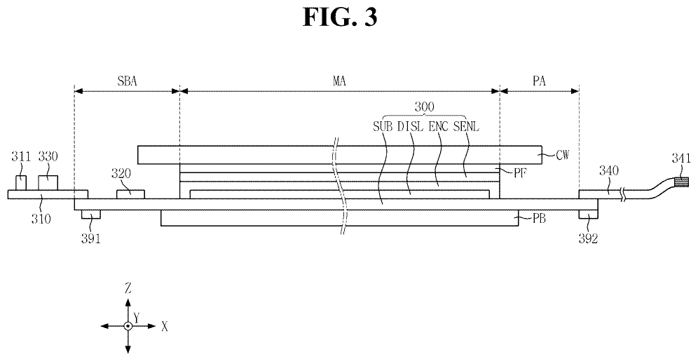

FIG. 3 is a cross-sectional view or side view (depending on the opaqueness of the non-display area NDA) depicting an example structure of a portion of the display device 10 with the protruded area PA and the sub-area SBA in unfolded states. FIG. 4 is a cross-sectional view of aside view depicting an example structure of the display device 10 with the protruded area PA and the sub-area SBA in folded states. FIG. 4 shows additional example components of the display device 10 as compared to FIG. 4.

Referring to FIGS. 3 and 4, the display device 10 may include a display panel 300, a polarizing film PF, a cover window CW, and a panel lower cover PB. The display panel 300 may include a substrate SUB, a display layer DISL, an encapsulation layer ENC and a sensor electrode layer SENL.

The substrate SUB may be made of an insulating material such as a polymer resin. The substrate SUB may be a flexible substrate capable of being subjected to bending, folding, rolling or the like.

In the main area MA, the display layer DISL may be disposed on the substrate SUB. The display layer DISL may be a layer that includes light emission areas to display an image. The display layer DISL may include a thin film transistor layer on which thin film transistors are formed, and a light emitting element layer in which light emitting elements for emitting light are disposed in the light emission areas.

Scan lines, data lines, power lines, etc. for driving the light emitting elements of the light emission area may be disposed in the display area DA of the display layer DISL. A scan driver for outputting scan signals to the scan lines and fan-out lines connecting the data lines with the display driving circuit 320 may be disposed in the non-display area NDA of the display layer DISL.

The encapsulation layer ENC may be disposed on the display layer DISL. The encapsulation layer ENC may be a layer for encapsulating the light emitting element layer of the display layer DISL to prevent oxygen or moisture from being permeated into the light emitting element layer of the display layer DISL. The encapsulation layer ENC may be disposed on an upper surface and sides of the display layer DISL.

The sensor electrode layer SENL may be disposed on the display layer DISL. The sensor electrode layer SENL may include sensor electrodes. The sensor electrode layer SENL may sense a touch through use of the sensor electrodes.

The polarizing film PF may be disposed on the sensor electrode layer SENL. The polarizing film PF may include a first base member, a linear polarizing plate, a phase delay film such as a λ/4 plate (quarter-wave plate), and a second base member. The first base member, the phase delay film, the linear polarizing plate and the second base member may be sequentially stacked on the sensor electrode layer SENL.

The cover window CW may be disposed on the polarizing film PF. The cover window CW may be attached onto the polarizing film PF by a transparent adhesive member such as an optically clear adhesive (OCA).

The panel lower cover PB may be disposed below the display panel 300. The panel lower cover PB may be attached to a lower surface of the display panel 300 through an adhesive member. The adhesive member may be a pressure sensitive adhesive (PSA). The panel lower cover PB may include at least one of a light blocking member for absorbing light incident from the outside, a buffer member for absorbing an impact from the outside or a heat dissipation member for efficiently discharging heat of the display panel 300.

The light blocking member may be disposed below the display panel 300. The light blocking member blocks transmission of light to prevent components disposed below the light blocking member, for example, the display circuit board 310, etc. from being viewed from an upper portion of the display panel 300. The light blocking member may include a light absorbing material such as a black pigment or a black dye.

The buffer member may be disposed below the light blocking member. The buffer member absorbs an external impact to prevent the display panel 300 from being damaged. The buffer member may include a single layer or a plurality of layers. For example, the buffer member may be formed of a polymer resin such as polyurethane, polycarbonate, polypropylene and polyethylene, or may include a material having elasticity, such as a sponge formed by foaming a rubber, a urethane-based material or an acrylic-based material.

The heat dissipation member may be disposed below the buffer member. The heat dissipation member may include a first heat dissipation layer including graphite or carbon nanotubes and a second heat dissipation layer formed of a metal thin film such as copper, nickel, ferrite or silver, which may shield electromagnetic waves and have excellent thermal conductivity.

According to an embodiment, as shown in FIG. 4, the substrate SUB may be bent in the sub-area SBA, and may be disposed below the display panel 300. The sub-area SBA of the substrate SUB may be attached to a lower surface of the panel lower cover PB by a first adhesive member 391. The first adhesive member 391 may be a pressure sensitive adhesive.

According to an embodiment, as shown in FIG. 4, the protruded area PA of the substrate SUB may be bent, and may be disposed below the display panel 300. The protruded area PA of the substrate SUB may be attached to the lower surface of the panel lower cover PB by a second adhesive member 392. The second adhesive member 392 may be a pressure sensitive adhesive.

The display circuit board 310 may be attached to the display pads DPD of the sub-area SBA of the substrate SUB by using a conductive adhesive member such as an anisotropic conductive film and an anisotropic conductive adhesive. The display circuit board 310 may include a connector 311 connected to the flexible circuit board 312. The display circuit board 310 may be connected to a connector 352 of the main circuit board 400 by the flexible circuit board 312.

The touch driving circuit 330 may be disposed on the display circuit board 310. The touch driving circuit 330 may generate touch data in accordance with a change in an electrical signal sensed in each of the sensor electrodes of the sensor electrode layer of the display panel 300 and transmit the touch data to the main processor 410 of the main circuit board 400, and the main processor 410 may calculate touch coordinates in which the touch has occurred, by analyzing the touch data.

The antenna circuit board 340 may be attached to the antenna pads APD of the protruded area PA of the substrate SUB by using a conductive adhesive member such as an anisotropic conductive film and an anisotropic conductive adhesive. The connector 351 of the antenna circuit board 340 may be connected to the connector 351 of the main circuit board 400. The protruded area PA may be connected to the main circuit board 400 by the antenna circuit board 340.

The main circuit board 400 may be a rigid printed circuit board (PCB) that is rigid and thus is not easily bent. The main processor 410 and the antenna driving circuit 350 may be disposed on the main circuit board 400.

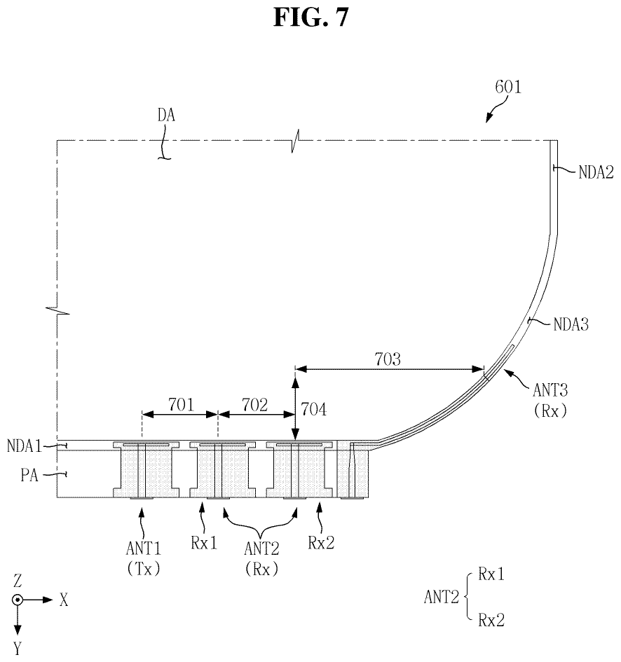

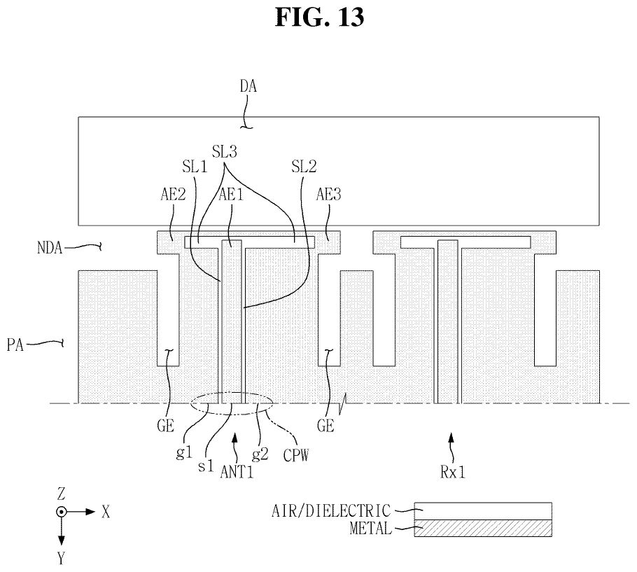

The antenna driving circuit 350 may be electrically connected to antennas (e.g., ANT1, ANT2 and ANT3 of FIG. 7, exemplified in detail in FIG. 13) of the display panel 300 through the antenna circuit board 340. The antenna circuit board 340 may be formed with an integrated circuit (IC).

The antenna driving circuit 350 may recognize a gesture of a user's hand by processing electromagnetic wave signals transmitted and received through antennas ANT. The antenna driving circuit 350 may sense biometric information such as a user's breathing and heart rate by processing electromagnetic wave signals transmitted and received through the antennas ANT.

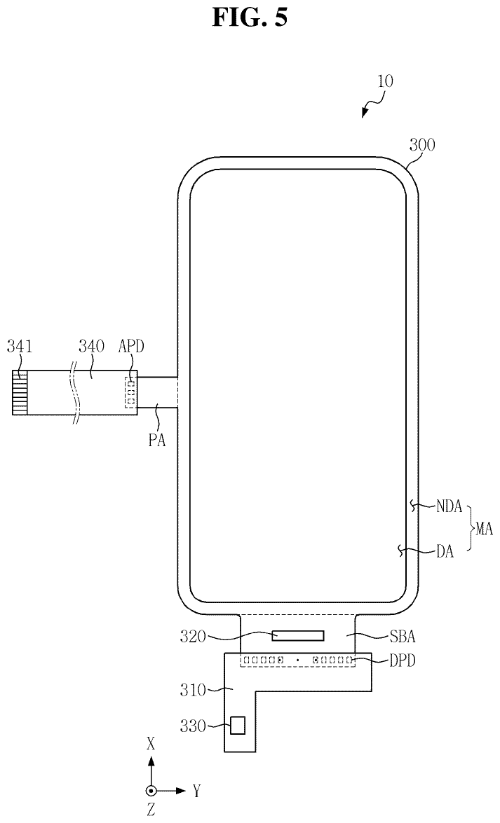

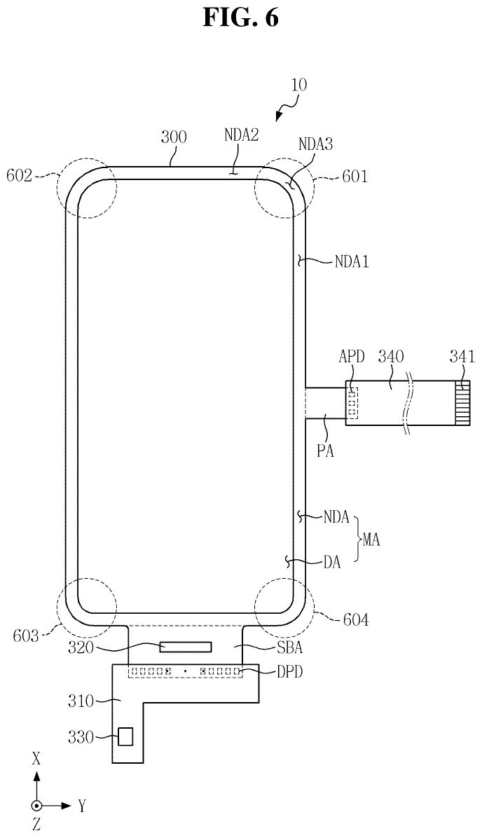

FIG. 5 is a plan view illustrating a display device according to another embodiment. FIG. 6 is a plan view illustrating a display device according to still another embodiment.

The embodiment of FIG. 5 is different from the embodiments of FIGS. 1 and 2 in that the protruded area PA is protruded from the left side of the main area MA in the Y direction. The embodiment of FIG. 6 is different from the embodiments of FIGS. 1 and 2 in that the protruded area PA is protruded from the right side of the main area MA in the Y direction. In FIGS. 5 to 6, the description repeated with the embodiments of FIGS. 1 and 2 will be omitted.

As shown in FIGS. 5 to 6, the protruded area PA may be protruded from one side of the main area MA, and one side of the main area MA may be any one of an upper side, a lower side, a left side and a right side of the main area MA.

Meanwhile, although not shown, the protruded area PA may be protruded from the lower side of the main area MA in the Y direction, and the protruded area PA may be disposed to be spaced apart from the sub-area SBA in the Y direction. In this case, a length of the protruded area PA in the X direction) may be smaller than a length of the sub-area SBA in the Y direction, but the embodiment of the present disclosure is not limited thereto.

FIG. 7 is a plan view illustrating any one corner, and a portion of one side. of a display panel according to an embodiment.

Referring to FIG. 7, the display panel 300 according to an embodiment may include antennas ANT1, ANT2 and ANT3 serving as sensors. For example, the antennas ANT1, ANT2 and ANT3 may be multi-input multi-output (MIMO) antennas that include a plurality of transmitting antennas ANT1 and a plurality of receiving antennas ANT2 and ANT3. (Detailed example configurations of antennas ANT1 and ANT2 are described later in connection with FIG. 13.) For example, the antennas ANT1, ANT2 and ANT3 may serve as sensors used to recognize gestures of a user's hand or to sense biometric information such as a user's breathing and heart rate. In this case, the transmitting antenna ANT1 may transmit a radar signal, which is reflected off the user's hand or other body part, and the reflected signal is sensed by the receiving antennas ANT2 and ANT3. Note that in other embodiments, the antennas ANT1, ANT2 and ANT3 may additionally or alternatively serve other functions, such as exchanging communication signals with other electronic devices.

According to an embodiment, the antennas ANT1, ANT2 and ANT3 may be adjacent to at least one corner of the display panel 300, and may be disposed at least partly in the non-display area NDA. (In the embodiment of FIG. 7, antennas ANT1 and ANT2 have dipole arms entirely in the non-display area NDA1. In other embodiments, not illustrated, the antennas ANT1 and ANT2 have dipole arms partly located within the non-display area NDA1 and partly in the protruded area PA. In still other embodiments, not illustrated, the antennas ANT1 and ANT2 are disposed entirely in the protruded area PA.) For example, as shown in FIG. 6, the non-display area (“region”) NDA may include a first non-display area NDA1 positioned on a long side of the display panel 300, a second non-display area NDA2 positioned on a short side of the display panel 300, and a third non-display area NDA3 connecting the first non-display area NDA1 with the second non-display area NDA2. Also, as shown in FIG. 6, the display panel 300 may have a rectangular shape when viewed on a plane, and may include a first corner 601, a second corner 602, a third corner 603 and a fourth corner 604. Although FIG. 7 will be described based on the first corner 601 shown in FIG. 6, the elements included in FIG. 7 may be disposed in at least one of the second corner 602, the third corner 603 or the fourth corner 604 of the display panel 300.

According to an embodiment, the display panel 300 includes at least one transmitting antenna ANT1 disposed in the first non-display area NDA1. For example, the transmitting antenna ANT1 may be disposed in the first non-display area NDA1 adjacent to any one corner of the display panel 300. In the present disclosure, a single transmitting (Tx) antenna ANT1 is described, but a plurality of transmitting antennas ANT1 may be included in other examples.

According to an embodiment, the display panel 300 includes a first receiving antenna ANT2 including a plurality of antennas, e.g., Rx1 and Rx2, forming a two (or higher) element array, and disposed in the first non-display area NDA1. For example, the antennas Rx1 and Rx2 may be collectively used to steer a receive path beam. The first receiving antenna ANT2 may be disposed in the first non-display area NDA1 adjacent to any one corner of the display panel 300, and may be adjacent to the transmitting antenna ANT1. In the present disclosure, it is described that the first receiving antenna ANT2 includes two receiving antennas Rx1 and Rx2, but the present disclosure is not limited thereto.

A distance in the X direction between the transmitting antenna ANT1 and the closest antenna (e.g., Rx1) of the first receiving antenna ANT2 may be a first distance 701. For example, the first distance 701 may be about 0.5λ (half a wavelength in free space) at a frequency of about 60 GHz.

The distance between the antennas Rx1 and Rx2 may be a second distance 702. For example, the second distance 702 may be about 0.5λ.

According to an embodiment, the display panel 300 includes a second receiving antenna ANT3 disposed in the third non-display area NDA3. For example, the second receiving antenna ANT3 is disposed in the third non-display area NDA3 corresponding to any one corner of the display panel 300. Unlike the plurality of antennas Rx1 and Rx2, the second receiving antenna ANT3 is oriented offset at a designated angle (e.g., about 55 degrees) from the transmitting antenna ANT1 on a plane. For instance, the antenna ANT3 is a monopole, and an axis running through a rod of the monopole intersects the X axis (running through dipole arms of the first transmitting antenna ANT1) at angle of about 55 degrees.

The plurality of first receiving antennas ANT2 and the second receiving antenna ANT3 may be spaced apart from each other by a third distance 703 in the X direction, and may be spaced apart from each other by a fourth distance 704 in the Y direction. For example, the third distance 703 may be about 1.2λ, and the fourth distance 704 may be about 0.5λ.

The at least one transmitting antenna ANT1 may be referred to herein interchangeably as a first antenna ANT1, and the following description will discuss the case of a single transmitting antenna ANT1 for ease of description. The first receiving antenna ANT2 may be a two element array including the antenna Rx1 (hereafter, “second antenna”) and the antenna Rx2 (hereafter, “third antenna”), which are oriented parallel to each other. (A common axis may run through dipole arms of each of the first antenna ANT1, the second antenna Rx1 and the third antenna Rx2.) The first antenna ANT1, the second antenna Rx1 and the third antenna Rx2 may be of the same type and have the same shape. For example, as noted above, the first antenna ANT1, the second antenna Rx1 and the third antenna Rx2 may be slotted dipole antennas.

According to an embodiment, the second receiving antenna ANT3 is or includes a fourth antenna Rx3, and a shape of the second receiving antenna ANT3 may be different from that of the first antenna ANT1, the second antenna Rx1 and the third antenna Rx2. For example, the fourth antenna Rx3, which is the second receiving antenna ANT3, may be a monopole antenna.

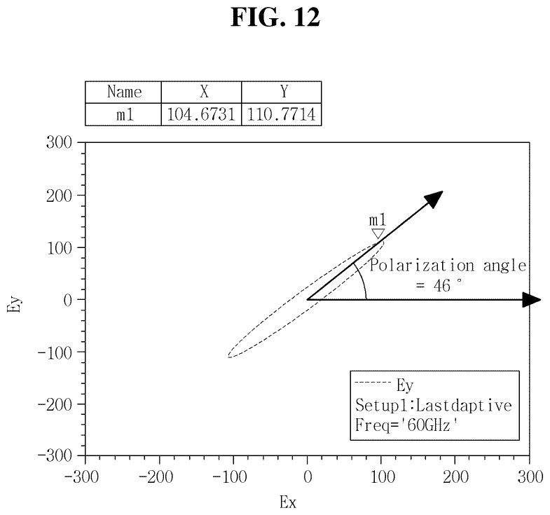

According to an embodiment, the first antenna ANT1, the second antenna Rx1 and the third antenna Rx2 are asymmetric dipole antennas having an asymmetric shape (with slotted dipole arms having different lengths) when viewed on a plane of the display panel 300. As described above, the example of the first antenna ANT1, the second antenna Rx1 and the third antenna Rx2 being asymmetric dipole antennas allows for the design of the polarization direction of the first antenna ANT1, the second antenna Rx1 and the third antenna Rx2 to be the same as the polarization direction of the fourth antenna Rx3. For example, as described later with reference to FIG. 12, the transmitting antenna ANT1, the receiving antenna ANT2 and the second receiving antenna ANT3 of the present disclosure may have substantially the same polarization direction.

When the transmitting antenna ANT1, the receiving antenna ANT2 and the second receiving antenna ANT3, which are shown in FIG. 7, are defined as one antenna group ANT1, ANT2 and ANT3, the antenna group ANT1, ANT2 and ANT3 may be disposed at one corner or a plurality of corners, which is (are) selected from the corners (601, 602, 603 and 604 of FIG. 6) included in the display panel 300. Thus, there may be a plurality of antenna groups, each including a set of antennas ANT1, ANT2 and ANT3, according to the present disclosure.

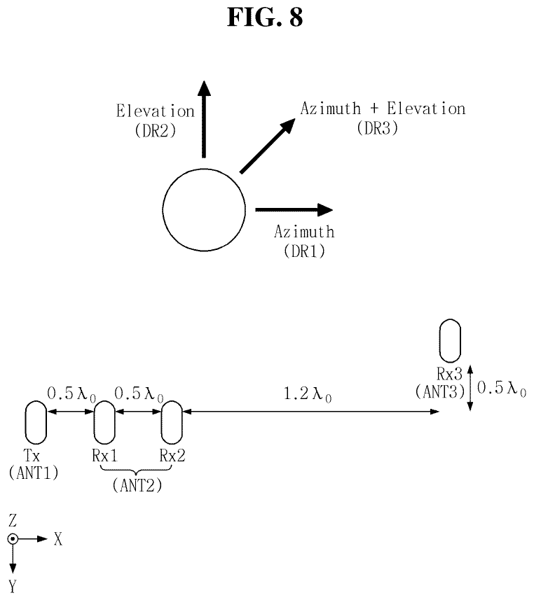

FIG. 8 is a conceptual view illustrating operations of antennas according to one embodiment.

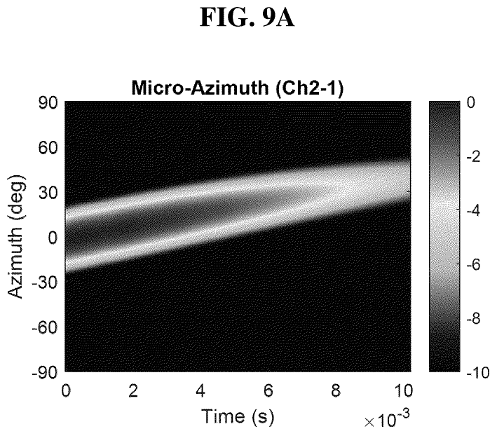

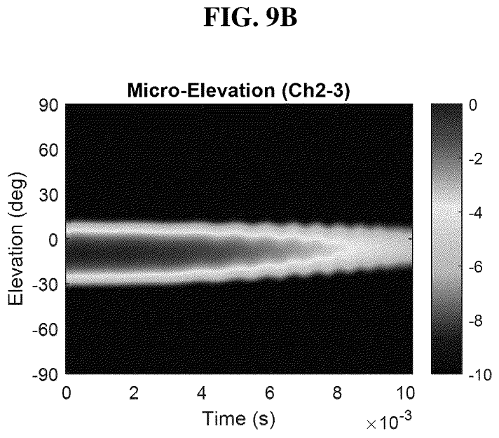

FIGS. 9A and 9B are radar images obtained by sensing an object, which is moving in a first direction, by antennas according to one embodiment.

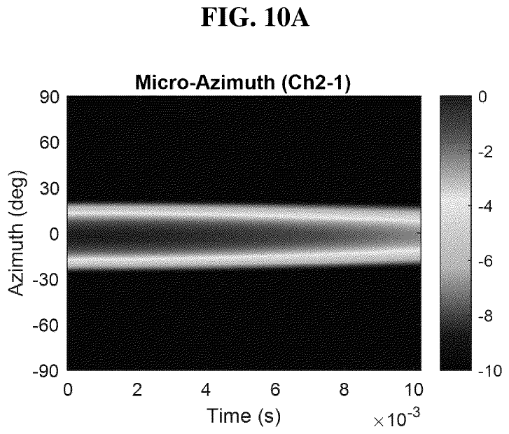

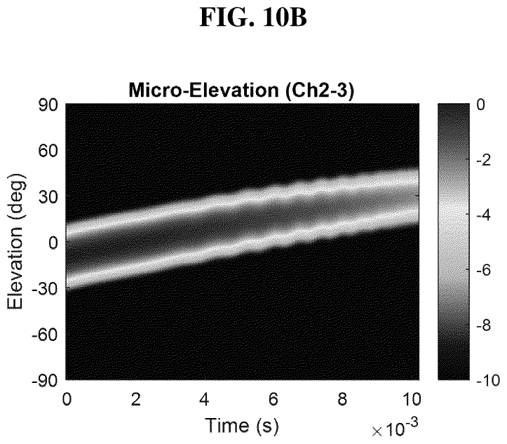

FIGS. 10A and 10B are radar images obtained by sensing an object, which is moving in a second direction, by antennas according to one embodiment.

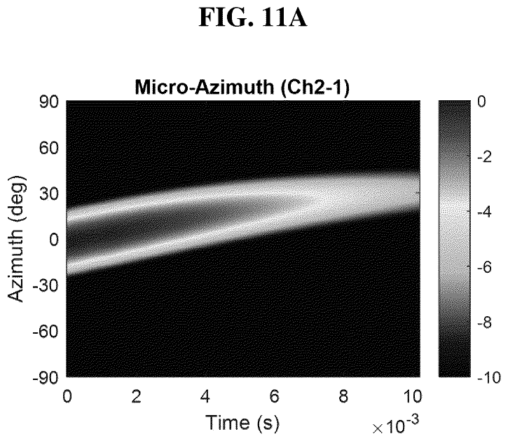

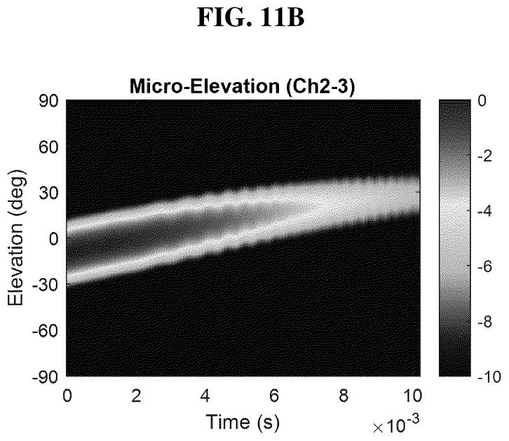

FIGS. 11A and 11B are radar images obtained by sensing an object, which is moving in a third direction, by antennas according to one embodiment.

For example, FIG. 8 is a conceptual view illustrating an experimental condition of radar images shown in FIGS. 9A to 11B. Referring to FIG. 8, the experimental condition is set so that the object moves in a first direction DR1 (e.g., Azimuth direction) while being spaced apart from the antennas in a normal direction (Z-direction) of the display panel 300 or moves in a second direction DR2 (e.g., Elevation direction) or moves in a third direction DR3 (e.g., Azimuth+Elevation direction).

In FIGS. 9A to 11B, an image pattern extended in a specific direction represents movement of an object sensed based on a phase difference of signals sensed from different receiving antennas.

Hereinafter, a result of sensing movement of an object by antennas according to one embodiment will be described with reference to FIGS. 8 to 11B.

Referring to FIGS. 8, 9A and 9B, the experimental condition is set so that the object moves in the first direction (e.g., Azimuth direction) while being spaced apart from the antennas in the normal direction (Z-direction) of the display panel 300. In this case, as shown in FIG. 9A, it may be seen that movement of the object from about 0° to about 40° is sensed due to a phase difference between the second and third antennas Rx1 and Rx2 disposed in parallel with each other. On the other hand, as shown in FIG. 9B, it may be seen that movement of the object is not sensed due to no phase difference between the third and fourth antennas Rx2 and Rx3.

Referring to FIGS. 8, 10aA and 10B, the experimental condition is set so that the object moves in the second direction (e.g., Elevation direction) while being spaced apart from the antennas in the normal direction (Z-direction) of the display panel 300. In this case, as shown in FIG. 10A, it may be seen that movement of the object is not sensed due to no phase difference between the second and third antennas Rx1 and Rx2 disposed in parallel with each other. On the other hand, as shown in FIG. 10B, it may be seen that movement of the object from about 0° to about 40° is sensed due to a phase difference between the third and fourth antennas Rx2 and Rx3.

Referring to FIGS. 8, 11A and 11B, the experimental condition is set so that the object moves in the third direction (e.g., Azimuth+Elevation direction) while being spaced apart from the antennas in the normal direction (Z-direction) of the display panel 300. In this case, as shown in FIG. 11A, it may be seen that movement of the object is sensed due to a phase difference between the second and third antennas Rx1 and Rx2 disposed in parallel with each other. Likewise, as shown in FIG. 11B, it may be seen that movement of the object from about 0° to about 30° is sensed due to a phase difference between the third and fourth antennas Rx2 and Rx3.

As described with reference to FIGS. 8 to 11B, it may be seen that the antenna groups ANT1, ANT2 and ANT3 according to one embodiment may effectively predict various moving directions of an external object.

FIG. 12 is a result of an experiment for polarization directions of antennas according to one embodiment.

Referring to FIG. 12, the first antenna ANT1, the second antenna Rx1 and the third antenna Rx2 according to an embodiment are asymmetric dipole antennas (with dipole arms of different lengths) having an asymmetric shape when viewed on a plane of the display panel 300. In this way, the reason why the first antenna ANT1, the second antenna Rx1 and the third antenna Rx2 are asymmetric dipole antennas is to design the polarization direction of the first antenna ANT1, the second antenna Rx1 and the third antenna Rx2 to be the same as the polarization direction of the fourth antenna Rx3 that is the second receiving antenna ANT3. For example, unlike the remaining antennas ANT1 and ANT2, the second receiving antenna ANT3 is disposed on a corner of the display panel 300, and thus may have an acute polarization direction.

In an embodiment of the present disclosure, the first antenna ANT1, the second antenna Rx1 and the third antenna Rx2 are designed as asymmetric dipole antennas such that they have the same polarization direction as that of the second receiving antenna ANT3. For example, as shown in FIG. 12, the fourth antenna Rx3 has a monopole antenna shape, is fed from a coplanar waveguide (CPW) transmission line and may have a polarization direction of about 46° as it is positioned on the corner of the display panel 300. In consideration of the polarization direction of the fourth antenna Rx3, the first antenna ANT1, the second antenna Rx1 and the third antenna Rx2 are designed as asymmetric dipole antennas. Therefore, the first antenna ANT1, the second antenna Rx1 and the third antenna Rx2 may have asymmetric slots to have a polarization direction of about 46°. According to one embodiment of the present disclosure, the polarization direction of the first antenna ANT1, the second antenna Rx1 and the third antenna Rx2 may be designed to be the same as the polarization direction of the fourth antenna Rx3 that is the second receiving antenna ANT3, whereby polarization loss may be reduced, and antenna efficiency may be increased.

FIG. 13 is a plan view illustrating the transmitting antenna ANT1 and the first receiving antenna ANT2 according to an embodiment. FIG. 13 schematically illustrates a first transmitting antenna ANT1 and any one (e.g., the second antenna Rx1) of the antennas of the first receiving antenna ANT2. Since the antennas Rx1 and Rx2 may have the same shape and dimensions, the description of the second antenna Rx1 may apply equally to the third antenna Rx2. In FIG. 13, shaded areas represent conductive material, e.g., metal, and white areas between the shaded areas represent air or dielectric.

Referring to FIG. 13, each of the first (transmitting) antenna ANT1 the second antenna Rx1 and the third antenna Rx2 (together forming the first receiving antenna ANT2) may have an antenna feed extending from a coplanar waveguide CPW. The coplanar waveguide CPW may include a signal conductor s1 (interchangeably, “feeding line”) separated on opposite sides by ground conductors g1 and g2. The antenna feed includes an antenna electrode AE1 separated on opposite sides by slots SL1 and SL2 to extended sections (in the Y direction) of the ground conductors g1 and g2.

Thus, the antenna electrode AE1 extends the feeding line s1. Returning momentarily to FIG. 7, a similar feeding line may extend from the protruded area to the right side corner of the display panel 300 to feed a transmission line (e.g., also coplanar waveguide) leading to the second receiving antenna ANT3.

As illustrated in FIG. 13, each of the first to third antennas ANT1, Rx1 and Rx2 may be slotted dipole antennas, with a dipole forming slot SL3 in the upper (radiating) portion of the dipole antenna. With the antenna electrode AE1 as a reference axis, since the left-side slot distance (to the slot edge abutting a conductive section AE2) is different from the right-side slot distance (to the slot edge abutting a conductive section AE3), the resulting dipole is an asymmetric slotted dipole. (The conductive section AE2 in conjunction with the left side of the slot SL3 may be referred to herein as a second antenna electrode of a slotted dipole antenna. The conductive section AE3 in conjunction with the right side of the slot SL3 may be referred to herein as a third antenna electrode of a slotted dipole antenna.) By designing the dipoles in this manner, the antenna boresight for each dipole may be skewed to align with the antenna boresight of the antenna ANT3. Further, the polarization directions of the first to third antennas ANT1 to ANT may be the same.

The second antenna Rx1 electrode is extended from the first antenna ANT1 electrode in one side direction (e.g., left direction), and has a first length in one side direction. The second antenna Rx1 electrode may include a slot.

The third antenna Rx2 electrode is extended from the first antenna ANT1 electrode in the other side direction (e.g., right direction) opposite to one side direction, and has a second length in the other side direction. In this case, the second length may be longer than the first length. The third antenna Rx2 electrode may include a slot, and a length of the slot of the third antenna Rx2 electrode may be longer than that of the slot of the second antenna Rx1 electrode.

According to an embodiment, a first ground conductor pattern (a ground conductor that is “patterned”) connected to the second antenna Rx1 electrode is disposed in one side direction from the feeding line, wherein the first ground pattern includes a first ground etched area GE1 disposed in parallel with the feeding line.

According to one embodiment, a second ground pattern connected to the third antenna Rx2 electrode is disposed in the other side direction from the feeding line, wherein the second ground pattern includes a second ground etched area GE2 disposed in parallel with the feeding line.

In the display panel 300 according to one embodiment, the ground etch areas GE1 and GE2 may be disposed between the adjacent antennas ANT1, Rx1 and Rx2, so that a coupling coefficient between the antennas may be reduced to about 12 dB or more.

In the description with reference to FIGS. 7 to 13, it has been described that the transmitting antenna ANT1 and the plurality of first receiving antennas ANT2 are disposed along the long side of the display panel 300, but the present disclosure is not limited thereto. In other embodiments, the transmitting antenna ANT1 and the plurality of first receiving antennas ANT2 are disposed along the short side of the display panel 300. For example, the non-display area may include a first non-display area NDA1 positioned on the short side of the display panel 300, a second non-display area NDA2 positioned on the long side of the display panel 300, a third non-display area NDA3 positioned at the corner of the display panel 300, connecting the first non-display area NDA1 with the second non-display area NDA2, and the display panel 300 may include at least one transmitting antenna ANT1 disposed at least partially in the first non-display area NDA1, a plurality of first receiving antennas ANT2 adjacent to at least one transmitting antenna ANT1 and disposed at least partially in the first non-display area NDA1 and a second receiving antenna ANT3 disposed in the third non-display area NDA3. In still other embodiments, the profile of the display device 10 is square, such that parallel first sides are orthogonal to parallel second sides; the transmitting antenna(s) ANT1 and the adjacent first receiving antenna ANT2 are disposed along any selected side of the first sides or the second sides; and the second receiving antenna ANT3 is disposed in a corner that connects the selected side to another one of the sides.

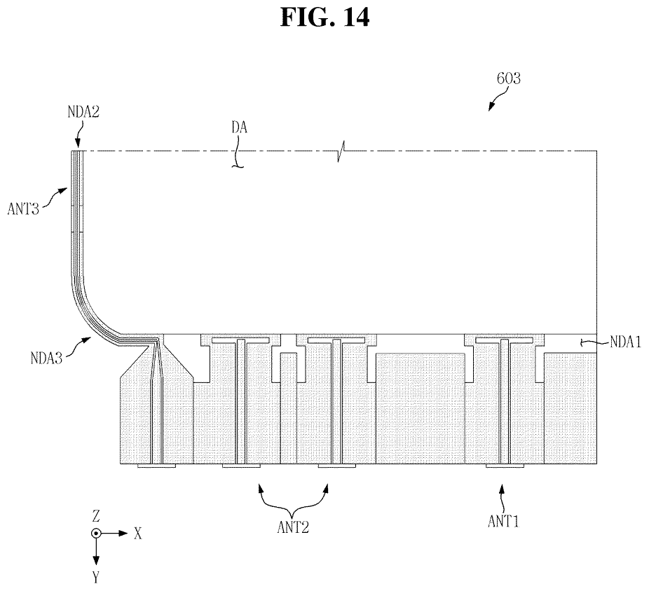

FIG. 14 is a plan view illustrating any one corner of a display panel according to an embodiment.

The embodiment of FIG. 14 differs from the embodiment of FIG. 7 in that the second receiving antenna ANT3 is disposed in the second non-display area NDA2. For example, the second receiving antenna ANT3 may not be disposed on the corner of the display panel 300 having a curved shape when viewed in a plan view, but is instead disposed on the long side or the short side of the display panel 300. (In the case of a square display device 10, the transmitting antenna ANT1 and the first receiving antenna ANT2 may be disposed along a first side, and the second receiving antenna ANT3 may be disposed along a second side, orthogonal to the first side, that connects to the first side.) Hereinafter, only features that differ from the embodiment of FIG. 14 will be described. Features in FIG. 14 not described below may be the same as the corresponding features described above with reference to FIGS. 7 to 13.

According to the embodiment of FIG. 14, the display panel 300 includes at least one transmitting antenna ANT1 disposed in the first non-display area NDA1, a plurality of first receiving antennas Rx1 and Rx3 (forming a first receiving antenna ANT2) adjacent to the at least one transmitting antenna ANT1 in the first non-display area NDA1 and a second receiving antenna ANT3 disposed in the second non-display area NDA2. Each of the antennas ANT1, Rx1 and Rx2 may be dipoles having dipole arms oriented in the first (X) direction. The second receiving antenna ANT3 may be a monopole having a rod axis oriented in the Y (second) direction.

In FIG. 14, as the second receiving antenna ANT3 is a monopole extended in the second direction, the polarization direction of the second receiving antenna ANT3 may be the second direction. Therefore, in the embodiment of FIG. 14, unlike the embodiment of FIG. 7, the transmitting antenna ANT1 and the plurality of first receiving antennas ANT2 may be designed as symmetrical dipole antennas. Thus, the first antenna ANT1 (transmitting antenna ANT1), each of the second antenna Rx1 and third antenna Rx2 (see FIG. 7) forming the first receiving antenna ANT2, are configured as dipole antennas, and may each include a symmetrical slot when viewed on a plane of the display panel 300. Therefore, the polarization direction of each of the first to third antennas (ANT1, Rx1 and Rx2) may be the same as the polarization direction of the fourth antenna (second receiving antenna) ANT3.

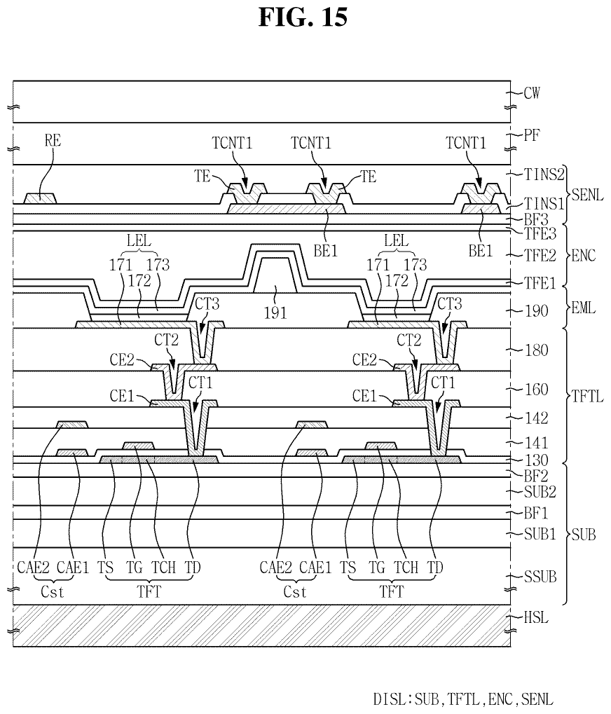

FIG. 15 is a cross-sectional view taken along a portion of a display area of a display panel according to one embodiment.

Referring to FIG. 15, the display panel 300 uses a substrate SUB having flexible characteristics as a base substrate.

A display layer DISL including a thin film transistor layer TFTL and a light emitting element layer EML may be disposed on one surface of the substrate SUB, an encapsulation layer ENC may be disposed on the display layer DISL, and a sensor electrode layer SENL including sensor electrodes SE may be disposed on the encapsulation layer ENC. A polarizing film PF may be disposed on the sensor electrode layer SENL, and a cover window CW may be disposed on the polarizing film PF.

The substrate SUB may include a support substrate SSUB, a first substrate SUB1, a first buffer film BF1, a second substrate SUB2 and a second buffer film BF2. The first substrate SUB1 may be disposed on the support substrate SSUB1, the first buffer film BF1 may be disposed on the first substrate SUB1, the second buffer film BF2 may be disposed on the first buffer film BF1, and the second buffer film BF2 may be disposed on the second substrate SUB2.

The support substrate SSUB may be a rigid substrate for supporting a first substrate SUB1 and a second substrate SUB2, which are flexible. The support substrate SSUB may be formed of a plastic material, such as polycarbonate (PC) and polyethylene terephthalate (PET), or glass.

The first substrate SUB1 and the second substrate SUB2 may be formed of an organic material such as an acrylic resin, an epoxy resin, a phenolic resin, a polyamide resin and a polyimide resin. The first substrate SUB1 and the second substrate SUB2 may be formed of the same organic material or different organic materials.

Each of the first buffer film BF1 and the second buffer film BF2 may be formed of an inorganic material such as a silicon nitride layer, a silicon oxynitride layer, a silicon oxide layer, a titanium oxide layer and an aluminum oxide layer. Alternatively, each of the first buffer film BF1 and the second buffer film BF2 may be formed of a multi-film in which a plurality of layers among a silicon nitride layer, a silicon oxynitride layer, a silicon oxide layer, a titanium oxide layer and an aluminum oxide layer are alternately stacked. The first buffer film BF1 and the second buffer film BF2 may be formed of the same inorganic material or different inorganic materials.

An active layer ACT including a channel area TCH, a source area TS and a drain area TD of the thin film transistor TFT may be disposed on the second buffer film BF2. The active layer ACT may include polycrystalline silicon, single crystal silicon, low-temperature polycrystalline silicon, amorphous silicon or an oxide semiconductor material. When the active layer ACT includes polycrystalline silicon or an oxide semiconductor material, the source area TS and the drain area TD in the active layer ACT may be conductive areas doped with ions to have conductivity.

A gate insulating film 130 may be formed on the active layer ACT of the thin film transistor TFT. The gate insulating film 130 may be formed of an inorganic film, for example, a silicon nitride layer, a silicon oxynitride layer, a silicon oxide layer, a titanium oxide layer or an aluminum oxide layer.

A gate electrode TG and a first capacitor electrode CAE1 of the thin film transistor TFT may be disposed on the gate insulating film 130. The gate electrode TG of the thin film transistor TFT may overlap the channel area TCH in the third direction DR3 (Z-axis direction). The gate electrode TG and the first capacitor electrode CAE1 may be formed of a single layer or multi-layer made of any one of molybdenum (Mo), aluminum (Al), chromium (Cr), gold (Au), titanium (Ti), nickel (Ni), neodymium (Nd) and copper (Cu) or their alloy.

A first interlayer insulating film 141 may be disposed on the gate electrode TG and the first capacitor electrode CAE1. The first interlayer insulating film 141 may be formed of an inorganic film, for example, a silicon nitride layer, a silicon oxynitride layer, a silicon oxide layer, a titanium oxide layer or an aluminum oxide layer. The first interlayer insulating film 141 may include a plurality of inorganic films.

A second capacitor electrode CAE2 may be disposed on the first interlayer insulating film 141. The second capacitor electrode CAE2 may overlap the first capacitor electrode CAE1 in the third direction DR3 (Z-axis direction). Therefore, a capacitor Cst may be formed by the first capacitor electrode CAE1, the second capacitor electrode CAE2 and an inorganic insulating dielectric film disposed between the first capacitor electrode CAE1 and the second capacitor electrode CAE2 to serve as a dielectric film. The second capacitor electrode CAE2 may be formed of a single layer or multi-layer made of any one of molybdenum (Mo), aluminum (Al), chromium (Cr), gold (Au), titanium (Ti), nickel (Ni), neodymium (Nd) and copper (Cu) or their alloy.

A second interlayer insulating film 142 may be disposed on the second capacitor electrode CAE2. The second interlayer insulating film 142 may be formed of an inorganic film, for example, a silicon nitride layer, a silicon oxynitride layer, a silicon oxide layer, a titanium oxide layer or an aluminum oxide layer. The second interlayer insulating film 142 may include a plurality of inorganic films.

A first connection electrode CE1 may be disposed on the second interlayer insulating film 142. The first connection electrode CE1 may be connected to the drain area TD through a first contact hole CT1 passing through the gate insulating film 130, the first interlayer insulating film 141 and the second interlayer insulating film 142. The first connection electrode CE1 may be formed of a single layer or multi-layer made of any one of molybdenum (Mo), aluminum (Al), chromium (Cr), gold (Au), titanium (Ti), nickel (Ni), neodymium (Nd) and copper (Cu) or their alloy.

A first organic film 160 for planarizing a step difference due to the thin film transistors TFTs may be disposed on the first connection electrode CE1. The first organic film 160 may be formed of an organic film such as an acrylic resin, an epoxy resin, a phenolic resin, a polyamide resin, a polyimide resin or a polyimide resin.

A second connection electrode CE2 may be disposed on the first organic film 160. The second connection electrode CE2 may be connected to the first connection electrode CE1 through a second contact hole CT2 passing through the first organic film 160. The second connection electrode CE2 may be formed as a single layer or multi-layer made of any one of molybdenum (Mo), aluminum (Al), chromium (Cr), gold (Au), titanium (Ti), nickel (Ni), neodymium (Nd) and copper (Cu) or their alloy.

A second organic film 180 may be disposed on the second connection electrode CE2. The second organic film 180 may be formed of an organic film such as an acrylic resin, an epoxy resin, a phenolic resin, a polyamide resin and a polyimide resin.

A light emitting element layer EML is disposed on the thin film transistor layer TFTL. The light emitting element layer EML may include light emitting elements LEL and a bank 190.

Each of the light emitting elements LEL may include a pixel electrode 171, a light emitting layer 172 and a common electrode 173. Each of light emission areas represents an area in which a pixel electrode 171, a light emitting layer 172 and a common electrode 173 are sequentially stacked and holes from the pixel electrode 171 and electrons from the common electrode 173 are coupled to each other in the light emitting layer 172 to emit light. In this case, the pixel electrode 171 may be an anode electrode, and the common electrode 173 may be a cathode electrode.

The pixel electrode 171 may be formed on the second organic film 180. The pixel electrode 171 may be connected to a first connection electrode ANDE1 through a third contact hole CT3 passing through the second organic film 180.

In a top emission structure in which light is emitted in a direction of the common electrode 173 based on the light emitting layer 172, the pixel electrode 171 may be formed of a single layer of molybdenum (Mo), titanium (Ti), copper (Cu) or aluminum (Al), or may be formed of a stacked structure (Ti/Al/Ti) of aluminum (Al) and titanium (Ti), a stacked structure (ITO/Al/ITO) of aluminum (Al) and indium tin oxide (ITO), an APC alloy, or a stacked structure (ITO/APC/ITO) of APC alloy and ITO to increase reflectance. The APC alloy is an alloy of silver (Ag), palladium (Pd) and copper (Cu).

The bank 190 may serve to define light emission areas of display pixels. To this end, the bank 190 may be formed on the second organic film 180 to expose a partial area of the pixel electrode 171. The bank 190 may cover an edge of the pixel electrode 171. The bank 190 may be disposed in a contact hole passing through the second organic film 180. Therefore, a third contact hole CT3 passing through the second organic film 180 may be filled by the bank 190. The bank 190 may be formed of an organic film such as an acrylic resin, an epoxy resin, a phenolic resin and a polyimide resin.

A spacer 191 may be disposed on the bank 190. The spacer 191 may serve to support a mask during a process of manufacturing the light emitting layer 172. The spacer 191 may be formed of an organic film such as an acryl resin, an epoxy resin, a phenolic resin, a polyamide resin and a polyimide resin.

The light emitting layer 172 is formed on the pixel electrode 171. The light emitting layer 172 may include an organic material to emit light of a predetermined color. For example, the light emitting layer 172 may include a hole transporting layer, an organic material layer and an electron transporting layer. The organic material layer may include a host and a dopant. The organic material layer may include a material that emits predetermined light, and may be formed using a phosphorescent material or a fluorescent material.

For example, the organic material layer of the light emitting layer 172 of a first light emission area for emitting light of a first color includes a host material that contains carbazole biphenyl (CBP) or 1,3-bis(carbazole-9-yl) (mCP), and may be a phosphorescent material that includes a dopant containing any one or more selected from PIQIr(acac)(bis(1-phenylisoquinoline) acetylacetonate iridium), PQIr(acac)(bis(1-phenylquinoline)acetylacetonate iridium), PQIr(tris(1-phenylquinoline)iridium) and PtOEP(octaethylporphyrin platinum). Alternatively, the organic material layer of the light emitting layer 172 of the first light emission area may be a fluorescent material that includes PBD:Eu(DBM)₃(Phen) or Perylene, but is not limited thereto.

The organic material layer of the light emitting layer 172 of a second light emission area for emitting light of a second color and a fourth light emission area includes a host material that includes CBP or mCP, and may be a phosphorescent material that includes a dopant material containing Ir(ppy)₃(fac tris(2-phenylpyridine)iridium). Alternatively, the organic material layer of the light emitting layer 172 of a second light emission area for emitting light of a second color and a fourth light emission area may be a fluorescent material that includes Alq3(tris(8-hydroxyquinolino)aluminum), but is not limited thereto.

The organic material layer of the light emitting layer 172 of a third light emission area for emitting light of a third color includes a host material that includes CBP or mCP, and may be a phosphorescent material that includes a dopant material containing (4,6-F2ppy)2Irpic or L2BD111, but is not limited thereto.

The common electrode 173 is formed on the light emitting layer 172. The common electrode 173 may be disposed to cover the light emitting layer 172. The common electrode 173 may be a common layer commonly formed in the light emission areas. A capping layer may be formed on the common electrode 173.

In the top emission structure, the common electrode 173 may be formed of a transparent conductive material (TCO) such as ITO and IZO, which may transmit light, or a semi-transmissive conductive material such as magnesium (Mg), silver (Ag) or an alloy of magnesium (Mg) and silver (Ag). When the common electrode 173 is formed of a semi-transmissive conductive material, light output efficiency may be enhanced by a micro cavity.

The encapsulation layer ENC may be formed on the light emitting element layer EML. The encapsulation layer ENC may include at least one inorganic film TFE1 or TFE3 to prevent oxygen or moisture from being permeated into the light emitting element layer EML. The encapsulation layer ENC may include at least one organic film to protect the light emitting element layer EML from particles such as dust. For example, the encapsulation layer ENC may include a first encapsulation inorganic film TFE1, an encapsulation organic film TFE2 and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed of a multi-layer in which one or more inorganic films of a silicon nitride layer, a silicon oxynitride layer, a silicon oxide layer, a titanium oxide layer and an aluminum oxide layer are alternately stacked. The encapsulation organic film TFE2 may be an organic film such as an acryl resin, an epoxy resin, a phenolic resin, a polyamide resin or a polyimide resin.

The sensor electrode layer SENL is disposed on the encapsulation layer ENC. The sensor electrode layer SENL may include sensor electrodes SE.

A third buffer film BF3 may be disposed on the encapsulation layer ENC. The third buffer film BF3 may be a layer having insulating and optical functions. The third buffer film BF3 may include at least one inorganic film. For example, the third buffer film BF3 may be formed of a multi-film in which one or more inorganic films among a silicon nitride layer, a silicon oxynitride layer, a silicon oxide layer, a titanium oxide layer and an aluminum oxide layer are alternately stacked. The third buffer film BF3 may be formed by a lamination process using a flexible material, a process such as spin coating and slit die coating, which uses a solution type material, or a deposition process. The third buffer film BF3 may be omitted.

First connection portions BE1 may be disposed on the third buffer film BF3. The first connection portions BE1 may be formed of a single layer of molybdenum (Mo), titanium (Ti), copper (Cu) or aluminum (Al), or may be formed of a stacked structure (Ti/Al/Ti) of aluminum (Al) and titanium (Ti), a stacked structure (ITO/Al/ITO) of aluminum (Al) and indium tin oxide (ITO), an APC alloy, or a stacked structure (ITO/APC/ITO) of APC alloy and ITO.

A first sensor insulating film TINS1 may be disposed on the first connection portions BE1. The first sensor insulating film TINS1 may be a layer having insulating and optical functions. The first sensor insulating film TINS1 may be formed of an inorganic film, for example, a silicon nitride layer, a silicon oxynitride layer, a silicon oxide layer, a titanium oxide layer or an aluminum oxide layer. The first sensor insulating film TINS1 may be formed by a lamination process using a flexible material, a process such as spin coating and slit die coating, which uses a solution type material, or a deposition process.

The sensor electrodes SE, i.e., driving electrodes TE and sensing electrodes RE may be disposed on the first sensor insulating film TNIS1. Also, dummy patterns (not shown) may be disposed on the first sensor insulating film TNIS1. The driving electrodes TE, the sensing electrodes RE and the dummy patterns do not overlap the light emission areas. The driving electrodes TE, the sensing electrodes RE and the dummy patterns may be formed of a single layer of molybdenum (Mo), titanium (Ti), copper (Cu) or aluminum (Al), or may be formed of a stacked structure (Ti/Al/Ti) of aluminum (Al) and titanium (Ti), a stacked structure (ITO/Al/ITO) of aluminum (Al) and indium tin oxide (ITO), an APC alloy, or a stacked structure (ITO/APC/ITO) of APC alloy and ITO.

A second sensor insulating film TINS2 may be disposed on the driving electrodes TE, the sensing electrodes RE and the dummy patterns (not shown). The second sensor insulating film TINS2 may be a layer having insulating and optical functions. The second sensor insulating film TINS2 may include at least one of an inorganic film or an organic film. The inorganic film may be a silicon nitride layer, a silicon oxynitride layer, a silicon oxide layer, a titanium oxide layer or an aluminum oxide layer. The organic film may be an acrylic resin, an epoxy resin, a phenolic resin, a polyamide resin or a polyimide resin. The second sensor insulating film TINS2 may be formed by a lamination process using a flexible material, a process such as spin coating and slit die coating, which uses a solution type material, or a deposition process.

A heat dissipation layer HSL of a panel lower cover PB may be disposed on a lower surface of the support substrate SSUB of the substrate SUB. The heat dissipation layer HSL may be formed of a metal thin film such as copper, nickel, ferrite or silver, which may shield electromagnetic waves and has excellent thermal conductivity.

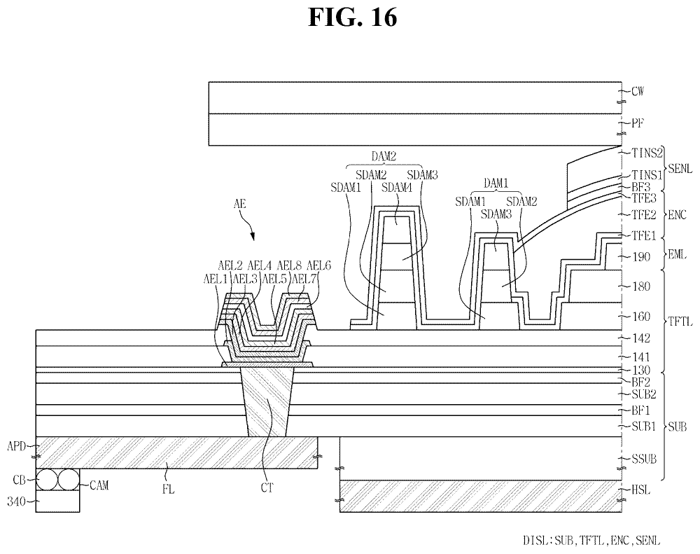

FIG. 16 is a cross-sectional view taken along a boundary between a protruded area of a display device according to one embodiment and a non-display area adjacent thereto.

Referring to FIG. 16, dams DAM1 and DAM2 surrounding the display area DA may be disposed in the non-display area NDA of the display panel 300. The dam DAM may include a first dam DAM1 of the encapsulation layer ENC and a second dam DAM2 disposed outside the first dam DAM1, but the present disclosure is not limited thereto. The first dam DAM1 and the second dam DAM2 may be disposed on the second interlayer insulating film 142.

The first dam DAM1 may include a first sub-dam SDAM1, a second sub-dam SDAM2 and a third sub-dam SDAM3, which are sequentially stacked. The first sub-dam SDAM1 may be formed of the same material as that of the first organic film 160, the second sub-dam SDAM2 may be formed of the same material as that of the second organic film 180, and the third sub-dam SDAM3 may be formed of the same material as that of the bank 190.

The second dam DAM2 may include a first sub-dam SDAM1, a second sub-dam SDAM2, a third sub-dam SDAM3 and a fourth sub-dam SDAM4, which are sequentially stacked. The first sub-dam SDMA1 may be formed of the same material as that of the first organic film 160, and the second sub-dam SDAM2 may be formed of the same material as that of the second organic film 180. The third sub-dam SDAM3 may be formed of the same material as that of the bank 190, and the fourth sub-dam SDAM4 may be formed of the same material as that of the spacer (191 of FIG. 15).

In FIG. 16, an antenna electrode AE may refer to the antennas described with reference to FIGS. 7 to 14. For example, the antenna electrode AE of FIG. 16 may represent at least one of the transmitting antenna ANT1, the first receiving antenna ANT2 or the second receiving antenna ANT3, which is shown in FIG. 7.

Referring to FIG. 16, the antenna electrode AE may include first to eighth antenna electrode layers AEL1 to AEL8, but the embodiment of the present disclosure is not limited thereto. The antenna electrode AE may include only some antenna electrode layers among the first to eighth antenna electrode layers AEL1 to AEL8.

The first antenna electrode layer AEL1 is formed by the same process as that of the gate electrode (TG of FIG. 15) and the first capacitor electrode (CAE1 of FIG. 15) of the thin film transistor (TFT of FIG. 15), and may be formed of the same material as that thereof.

The second antenna electrode layer AEL2 may be disposed on the first antenna electrode layer AEL1 exposed without being covered by the first interlayer insulating film (141 of FIG. 15). The second antenna electrode layer may be formed by the same process as that of the second capacitor electrode (CAE2 of FIG. 15), and may be formed of the same material as that thereof.

The third antenna electrode layer AEL3 may be disposed on the second antenna electrode layer AEL2 exposed without being covered by the second interlayer insulating film (142 of FIG. 15). The third antenna electrode layer AEL3 may be formed by the same process as that of the first connection electrode (CE1 of FIG. 15), and may be formed of the same material as that thereof.

The fourth antenna electrode layer AEL4 may be disposed on the third antenna electrode layer AEL3. The fourth antenna electrode layer AEL4 may be formed by the same process as that of the second connection electrode (CE2 of FIG. 15), and may be formed of the same material as that thereof.

The fifth antenna electrode layer AEL5 may be disposed on the fourth antenna electrode layer AEL4. The fifth antenna electrode layer AEL5 may be formed by the same process as that of the pixel electrode (171 of FIG. 15), and may be formed of the same material as that thereof.

The sixth antenna electrode layer AEL6 may be disposed on the fifth antenna electrode layer AEL5. The sixth antenna electrode layer AEL6 may be formed by the same process as that of the common electrode (173 of FIG. 15), and may be formed of the same material as that thereof.

The seventh antenna electrode layer AEL7 may be disposed on the sixth antenna electrode layer AEL6. The seventh antenna electrode layer AEL7 may be formed by the same process as that of the first connection portion (BE1 of FIG. 15) of the sensor electrode layer SENL, and may be formed of the same material as that thereof.

The eighth antenna electrode layer AEL8 may be disposed on the seventh antenna electrode layer AEL7. The eighth antenna electrode layer AEL8 may be formed by the same process as that of the driving electrode (TE of FIG. 15), the sensing electrode (RE of FIG. 15) and/or the dummy pattern (not shown) of the sensor electrode layer SENL, and may be formed of the same material as that thereof.

A through hole (or contact hole) CT may pass through the first substrate SUB1, the first buffer film BF1, the second substrate SUB2 and the second buffer film BF2 of the substrate SUB. Also, the through hole CT may pass through the gate insulating film 130.

The antenna electrode AE may be in contact with a feeding line FL through the through hole CT.

An antenna pad APD electrically connected to the feeding line FL may be disposed at an end of the feeding line FL. The feeding line FL and the antenna pad APD may be disposed on a lower surface of the first substrate SUB1 of the substrate SUB. Since a protruded area PA is disposed to be bent below a main area MA, the support substrate SSUB of the substrate SUB may be removed from the protruded area PA in which the feeding line FL is disposed.

The antenna pad APD may be connected to an antenna circuit board 340 by using an anisotropic conductive film ACF including a conductive ball CB and a conductive adhesive member CAM such as an anisotropic conductive adhesive.

In concluding the detailed description, those skilled in the art will appreciate that many variations and modifications can be made to the example embodiments without substantially departing from the principles of the present inventive concept. Therefore, the disclosed example embodiments have been presented in a generic and descriptive sense only and not for purposes of limitation.

What is claimed is:

1. A display device comprising
a display panel including a display area and a non-display region disposed outside the display area, the display panel including a flexible substrate including a protruded area extended from a portion of the non-display region, the display panel having a long side and a short side; and
an antenna circuit board connected to the protruded area,
wherein the non-display region includes a first non-display area along the long side of the display panel, a second non-display area along the short side of the display panel and a third non-display area on a corner of the display panel, connecting the first non-display area with the second non-display area, and
the display panel includes at least one transmitting antenna disposed at least partly in or proximate to the first non-display area, a plurality of first receiving antennas disposed adjacent to the at least one transmitting antenna and at least partly in or proximate to the first non-display area, and a second receiving antenna disposed in the third non-display area.

2. The display device of claim 1, wherein the at least one transmitting antenna includes a first antenna, and the plurality of first receiving antennas include a second antenna and a third antenna, which are oriented in parallel to one other and receive with the same polarization.

3. The display device of claim 2, wherein the first to third antennas each have the same shape.

4. The display device of claim 3, wherein the shape of the first to third antennas is different from a shape of the second receiving antenna.

5. The display device of claim 4, wherein the first to third antennas are dipole antennas, and
the second receiving antenna is a monopole antenna.

6. The display device of claim 5, wherein the first to third antennas have an asymmetric shape when viewed on a plane of the display panel.

7. The display device of claim 6, wherein each of the first to third antennas includes:
a first antenna electrode extended from a feed line;
a second antenna electrode extended in a first side direction from the first antenna electrode, having a first length in the first side direction; and
a third antenna electrode extended from the second antenna electrode in an opposite side direction to the first side direction, having a second length in the opposite side direction different from the first length.

8. The display device of claim 7, wherein a first ground conductive pattern connected to the second antenna electrode is disposed in the first side direction from the feeding line, the first ground pattern including a first ground etched area forming a first elongated opening disposed in parallel with the feeding line, and
a second ground pattern connected to the third antenna electrode is disposed in the opposite side direction from the feeding line, the second ground pattern including a second ground etched area forming a second elongated opening disposed in parallel with the feeding line.

9. A display device comprising:
a display panel including a display area and a non-display region disposed outside the display area, the display panel including a flexible substrate including a protruded area extended from a portion of the non-display region, the display panel having a long side and a short side; and
an antenna circuit board connected to the protruded area,
wherein the non-display region includes a first non-display area along the short side of the display panel, a second non-display area along the long side of the display panel and a third non-display area positioned on a corner of the display panel, connecting the first non-display area with the second non-display area, and
the display panel includes at least one transmitting antenna disposed at least partly in or proximate to the first non-display area, a plurality of first receiving antennas adjacent to the at least one transmitting antenna and disposed at least partly in or proximate to the first non-display area, and a second receiving antenna disposed in the third non-display area.

10. The display device of claim 9, wherein the at least one transmitting antenna includes a first antenna, and the plurality of first receiving antennas include a second antenna and a third antenna, which are disposed in parallel with each other.

11. The display device of claim 10, wherein the first to third antennas have the same shape.

12. The display device of claim 11, wherein the shape of the first to third antennas is different from a shape of the second receiving antenna.

13. The display device of claim 12, wherein the first to third antennas have an asymmetric shape when viewed on a plane of the display panel.

14. A display device comprising:
a display panel including a display area and a non-display region disposed outside the display area, the display panel including a flexible substrate including a protruded area extended from a portion of the non-display area, the display panel having a long side and a short side; and
an antenna circuit board connected to the protruded area,
wherein the non-display area includes a first non-display area along a long side of the display panel, a second non-display area along a short side of the display panel and a third non-display area positioned on a corner of the display panel, connecting the first non-display area with the second non-display area, and
the display panel includes at least one transmitting antenna disposed at least partly in or proximate to the first non-display area, a plurality of first receiving antennas disposed adjacent to the at least one transmitting antenna and at least partly in or proximate to the first non-display area, and a second receiving antenna disposed in the second non-display area.

15. The display device of claim 14, wherein the at least one transmitting antenna includes a first antenna, and the plurality of first receiving antennas include a second antenna and a third antenna, which are disposed in parallel with each other.

16. The display device of claim 15, wherein the first to third antennas have the same shape.

17. The display device of claim 16, wherein the shape of the first to third antennas is different from a shape of the second receiving antenna.

18. The display device of claim 17, wherein the first to third antennas are dipole antennas, and the second receiving antenna is a monopole antenna.

19. The display device of claim 18, wherein the first to third antennas have a symmetric shape when viewed on a plane of the display panel.

20. The display device of claim 19, wherein a polarization direction of each of the first to third antennas is the same as a polarization direction of the second receiving antenna.

21. A display device comprising
a display panel including a display area and a non-display region disposed outside the display area, the display panel including a flexible substrate including a protruded area extended from a portion of the non-display region, the display panel having a first side and a second side orthogonal to the first side; and
an antenna circuit board connected to the protruded area,
wherein the non-display region includes a first non-display area along the first side of the display panel, a second non-display area along the second side of the display panel and a third non-display area on a corner of the display panel, connecting the first non-display area with the second non-display area, and
the display panel includes at least one transmitting antenna disposed at least partly in or proximate to the first non-display area, a plurality of first receiving antennas disposed adjacent to the at least one transmitting antenna and at least partly in or proximate to the first non-display area, and a second receiving antenna disposed in the third non-display area.
